(19) United States
(12) Patent Application Publication
(10) Pub. No.: US 2018/0374732 A1
(43) Pub. Date: Dec. 27, 2018

(54) APPARATUS FOR TRANSPORTATION OF A SUBSTRATE, APPARATUS FOR VACUUM PROCESSING OF A SUBSTRATE, AND METHOD FOR MAINTENANCE OF A MAGNETIC LEVITATION SYSTEM

(71) Applicant: Applied Materials, Inc., Santa Clara, CA (US)

(72) Inventors: Wolfgang KLEIN, Wörth (DE); Oliver HEIMEL, Wabern (DE); Simon LAU, Alzenau (DE)

(73) Assignee: Applied Materials, Inc., Santa Clara, CA (US)

(21) Appl. No.: 15/747,075

(22) PCT Filed: Aug. 21, 2015
(86) PCT No.: PCT/EP2015/069264

§ 371 Date: Jan. 23, 2018

(51) Int. Cl. H01L 21/677; H01L 21/67; C23C 14/35; C23C 14/50; C23C 14/54

(52) U.S. Cl. CPC H01L 21/67709; H01L 21/6776; H01L 21/67712; C23C 14/54; C23C 14/351; C23C 14/505; H01L 21/67276

(57) ABSTRACT

An apparatus for transportation of a substrate is provided. The apparatus includes a vacuum chamber having a chamber wall configured to separate a vacuum side from an atmospheric side and a magnetic levitation system configured for a contactless levitation of a substrate carrier in the vacuum chamber. The magnetic levitation system includes at least one magnetic device configured for providing a magnetic force acting on the substrate carrier during transportation of the substrate carrier in the vacuum chamber along a transportation path and at least one holding unit configured to hold the at least one magnetic device being accessible from the atmospheric side.

### FIELD

Embodiments of the present disclosure relate to an apparatus for transportation of a substrate, an apparatus for vacuum processing of a substrate, and a method for maintenance of a magnetic levitation system. Embodiments of the present disclosure particularly relate to a sputter deposition apparatus and method for maintenance of a contactless magnetic levitation system thereof.

### BACKGROUND

Techniques for layer deposition on a substrate include, for example, thermal evaporation, sputtering deposition and chemical vapor deposition (CVD). A sputter deposition process can be used to deposit a material layer on the substrate, such as a layer of an insulating material. Substrate carriers can be used for supporting the substrate during a deposition process, such as a sputter deposition process. Substrate carriers can be transported in a vacuum chamber using a transportation system configured for conveying the substrate carrier having the substrate position thereon.

Transportation systems can be provided inside the vacuum chamber and are thus positioned within a vacuum environment. For maintenance, service and/or repair of the transportation system or components thereof, the vacuum chamber has to be vented in order to gain access to the transportation system. After maintenance, service and/or repair, the vacuum has to be re-established in the vacuum chamber. Impurities, such as residual gases, have to be removed from the vacuum chamber in order to obtain suitable vacuum conditions and to avoid contamination of the deposited layers. Such a procedure including the venting and the re-establishing of the vacuum is time consuming, leading to a considerable downtime of the deposition apparatus.

In view of the above, there is a need for new apparatuses for transportation of a substrate, apparatuses for vacuum processing of a substrate, and methods for maintenance of a magnetic levitation system that reduce a downtime of the deposition apparatus. There is particularly a need for new apparatuses and methods for maintenance thereof that facilitate maintenance, service and/or repair of a transportation system or components thereof.

### SUMMARY

In light of the above, an apparatus for transportation of a substrate, an apparatus for vacuum processing of a substrate, and methods for maintenance of a magnetic levitation system are provided. Further aspects, benefits, and features of the present disclosure are apparent from the claims, the description, and the accompanying drawings.

According to an aspect of the present disclosure, an apparatus for transportation of a substrate is provided. The apparatus includes a vacuum chamber having a chamber wall configured to separate a vacuum side from an atmospheric side and a magnetic levitation system configured for a contactless levitation of a substrate carrier in the vacuum chamber. The magnetic levitation system includes at least one magnetic device configured for providing a magnetic force acting on the substrate carrier during transportation of the substrate carrier in the vacuum chamber along a transportation path and at least one holding unit configured to hold the at least one magnetic device being accessible from the atmospheric side.

According to another aspect of the present disclosure, an apparatus for vacuum processing of a substrate is provided. The apparatus includes a vacuum chamber having a chamber wall configured to separate a vacuum side from an atmospheric side, and a magnetic levitation system configured for a contactless levitation of a substrate carrier in the vacuum chamber. The magnetic levitation system includes at least one magnetic device configured for providing a magnetic force acting on the substrate carrier during transportation of the substrate carrier in the vacuum chamber along a transportation path, and at least one holding unit configured to hold the at least one magnetic device being accessible from the atmospheric side. The apparatus further includes one or more processing tools in the vacuum chamber, wherein the one or more processing tools are arranged along the transportation path.

According to yet another aspect of the present disclosure, a method for maintenance of a magnetic levitation system is provided. The magnetic levitation system is configured for a contactless levitation of a substrate carrier in a vacuum chamber. The method includes accessing at least one magnetic device of the magnetic levitation system held by a holding unit from an atmospheric side of the vacuum chamber.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an apparatus for transportation of a substrate according to embodiments described herein;

FIG. 2 shows a schematic view of an apparatus for transportation of a substrate according to further embodiments described herein;

FIG. 3 shows a schematic view of a section of an apparatus for transportation of a substrate according to yet further embodiments described herein;

FIG. 4 shows a schematic view of a section of an apparatus for transportation of a substrate according to further embodiments described herein;

FIG. 5 shows a schematic view of an apparatus for layer deposition on a substrate according to embodiments described herein; and

FIG. 6 shows a flow chart of a method for maintenance of a magnetic levitation system according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on, or in conjunction with, other embodiments to yield yet a further embodiment. It is intended that the description includes such modifications and variations.

Transportation systems can utilize magnetic levitation systems for a contactless transportation of substrate carriers in a vacuum chamber, for example, a vacuum deposition chamber. The term “contactless” or as used throughout the present disclosure can be understood in the sense that a weight of the substrate carrier is not held by a mechanical contact or mechanical forces, but is held by a magnetic force. Specifically, the substrate carrier is held in a levitating or floating state using magnetic forces instead of mechanical forces. As an example, the transportation system has no mechanical means, such as rollers, that support the weight of the substrate carrier. In some implementations, there can be no mechanical contact between the substrate carrier and the transportation system at all. The contactless levitation and the optional contactless transportation of the substrate carrier is beneficial in that no particles are generated due to a mechanical contact between the substrate carrier and sections of the transportation system, such as rollers, during the transport of the substrate carrier. Accordingly, a purity of the layers deposited on the substrate can be improved, in particular since a particle generation is minimized when using the contactless transportation.

The magnetic levitation system can include various components, such as one or more magnetic devices, provided within an atmospheric box inside the vacuum chamber. For maintenance, service and/or repair of the transportation system or the components thereof, the vacuum chamber has to be vented in order to gain access to the atmospheric box. After maintenance, service and/or repair, the vacuum has to be re-established in the vacuum chamber. Impurities, such as residual gases, have to be removed from the vacuum chamber in order to obtain suitable vacuum conditions and to minimize or even avoid contamination of, for example, the deposited layers. Such a procedure including the venting and the re-establishing of the vacuum is time consuming, leading to a considerable downtime of the deposition apparatus.

The present disclosure provides an apparatus for transportation of a substrate having a magnetic levitation system, wherein at least some of the components of the magnetic levitation system are provided at the atmospheric side of the vacuum chamber. In other words, at least some of the components of the magnetic levitation system are not provided within the vacuum environment. The components of the magnetic levitation system, such as at least one magnetic device held by a holding unit, are provided at the atmospheric side and are accessible without breaching the vacuum inside the vacuum chamber. A downtime of the apparatus, such as the deposition apparatus, for maintenance, service, and/or repair can be reduced. Further, maintenance, service, and/or repair of the magnetic levitation system, and in particular of the at least one magnetic device, is facilitated.

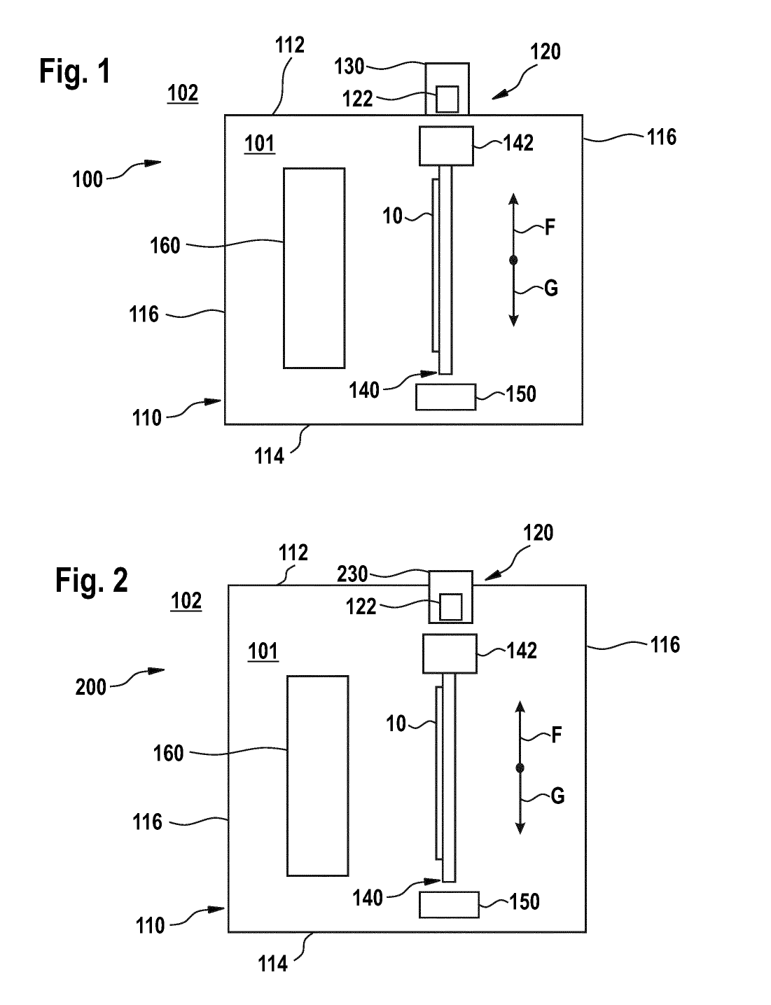

FIG. 1 shows a schematic view of an apparatus 100 for transportation of a substrate 10 according to embodiments described herein. According to some embodiments, the apparatus 100 can be configured for layer deposition, for example, sputter deposition on a substrate 10.

The apparatus 100 includes a vacuum chamber 110 having a chamber wall configured to separate a vacuum side 101 from an atmospheric side 102. In some implementations, the vacuum chamber 110 can be a vacuum deposition chamber. The apparatus 100 further includes a magnetic levitation system 120 configured for a contactless levitation of a substrate carrier 140. The magnetic levitation system 120 includes at least one magnetic device 122 configured for providing a magnetic force acting on the substrate carrier 140 during transportation of the substrate carrier 140 in the vacuum chamber 110 along a transportation path. In some embodiments, the magnetic levitation system 120 can be configured for a contactless transportation of the substrate carrier 140 along the transportation path. The magnetic levitation system 120 further includes at least one holding unit 130 configured to hold the at least one magnetic device 122 being accessible from the atmospheric side 102. In other words, the at least one holding unit 130 has a configuration that allows the at least one magnetic device 122 to be accessed from the atmospheric side 102, for example, for maintenance, repair or exchange.

Terms like “vacuum”, “vacuum side” and “vacuum environment” as used throughout the disclosure can be understood as a space that is substantially devoid of matter, e.g., a space from which all or most of the air or gas has been removed, except for process gases that are used in a deposition process, such as a sputter deposition process. As an example, the terms like “vacuum”, “vacuum side” and “vacuum environment” can be understood in the sense of a technical vacuum having a vacuum pressure of less than, for example, 10 mbar. The apparatus 100 for layer deposition can include one or more vacuum pumps, such as turbo pumps and/or cryo-pumps, connected to the vacuum chamber 110 for generation of the vacuum inside the vacuum chamber 110. The term “atmospheric side” as used throughout the disclosure can be understood as a space with atmospheric pressure or ambient pressure. Specifically, the atmospheric side 102 can be understood as being outside of the vacuum chamber 110.

According to some embodiments, which can be combined with other embodiments described herein, the at least one holding unit 130 is configured to hold the at least one magnetic device 122 being accessible from the atmospheric side 102 when a vacuum environment is present in the vacuum chamber 110. The at least one magnetic device 122 can be accessed for maintenance, service or exchange while the vacuum is present in the vacuum chamber 110. In other words, the vacuum chamber 110 has not to be vented for maintenance, service or exchange of the at least one magnetic device 122. A downtime of the apparatus 100 for maintenance, service and/or exchange of the at least one magnetic device 122 can be reduced.

The vacuum chamber 110 has a plurality of chamber walls enclosing a space that defines the vacuum side 101. In some implementations, the plurality of chamber walls can include a top wall 112, a bottom wall 114 and one or more side walls 116. The at least one holding unit 130 can be provided at one chamber wall of the plurality of chamber walls, for example, the top wall 112 or the bottom wall 114. However, the present disclosure is not limited thereto, and the holding unit 130 can be provided at any suitable portion of the vacuum chamber 110 that allows for an access of the at least one magnetic device 122 from the atmospheric side 102.

The substrate carrier 140 is configured to support the substrate 10, for example, during a layer deposition process, such as a sputtering process. The substrate carrier 140 can include a plate or a frame configured for supporting the substrate 10, for example, using a support surface provided by the plate or frame. Optionally, the substrate carrier 140 can include one or more holding devices (not shown) configured for holding the substrate 10 at the plate or frame. The one or more holding devices can include at least one of mechanical and/or magnetic clamps.

According to some embodiments, which can be combined with other embodiments described herein, the substrate carrier 140 is configured for supporting the substrate 10 in a substantially vertical orientation, in particular during the layer deposition process. As used throughout the present disclosure “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Yet, the substrate orientation during the layer deposition process is considered substantially vertical, which is considered different from the horizontal substrate orientation.

The at least one magnetic device 122 is configured for providing the magnetic force F acting on the substrate carrier 140. Specifically, the at least one magnetic device 122 is configured to generate a magnetic field at the position of the substrate carrier 140, wherein the magnetic field provides the magnetic force F. The magnetic force F acts on the substrate carrier 140 to contactlessly hold the substrate carrier 140 in a floating state. As an example, the magnetic force F provided by the at least one magnetic device 122 can keep or hold the substrate carrier 140 having the substrate 10 positioned thereon in the substantially vertical orientation, for example, during the transportation of the substrate carrier 140 through the vacuum chamber 110.

The magnetic force F is sufficient to hold the substrate carrier 140 having the substrate 10 positioned thereon in the floating state. Specifically, the magnetic force F can be equal to a total weight of the substrate carrier 140. The total weight of the substrate carrier 140 can include at least a weight of the (empty) substrate carrier 140 and a weight of the substrate 10. As an example, a magnetic field generated by the at least one magnetic device 122 is selected such that the magnetic force F is equal to the total weight G of the substrate carrier 140 in order to keep the substrate carrier 140 in the suspended or levitating state.

The magnetic force F acts on the substrate carrier 140 when the substrate carrier 140 is positioned within a predetermined range or distance from the at least one magnetic device 122. Specifically, the magnetic force F acts on the substrate carrier 140 during transportation of the substrate carrier 140, for example, when at least a portion of the substrate carrier 140 is in the vicinity of (e.g. below) the at least one magnetic device 122.

In some embodiments, a distance or spacing between the at least one magnetic device 122 and the substrate carrier 140 (e.g., in the vertical direction) is less than 1 cm, specifically less than 0.5 cm, and is more specifically less than 0.3 cm when the magnetic force F is acting on the substrate carrier 140 during the transportation of the substrate carrier 140. In some implementations, the distance or spacing between the at least one magnetic device 122 and the substrate carrier 140 is in a range of 0.5 to 5 mm, specifically in a range of 1 to 2 mm, and can more specifically be about 1.5 mm. According to some embodiments, the distance or spacing between the at least one magnetic device 122 and the substrate carrier 140 (e.g., in the vertical direction) is less than 1 cm, specifically less than 0.5 cm, and more specifically less than 0.3 cm when the substrate carrier 140 is positioned directly below the at least one magnetic device 122. However, it is to be understood that the distance between the at least one magnetic device 122 and the substrate carrier 140 is not limited thereto. Any suitable distance or spacing can be chosen that allows the magnetic force F provided by the at least one magnetic device 122 to act on the substrate carrier 140 to hold the substrate carrier 140 in the floating state.

According to some embodiments, which can be combined with other embodiments described therein, the magnetic field generated by the at least one magnetic device 122 is a static or dynamic magnetic field. The magnetic field, specifically a magnetic field strength, can be dynamically adjusted. As an example, the magnetic field can be adjusted based on the position of the substrate carrier 140 such that the substrate carrier 140 is kept in the floating or suspended state.

In some implementations, the substrate carrier 140 can include one or more magnet units 142. As an example, the one or more magnet units 142 can be provided by the material of the substrate carrier 140. In other words, the material of at least a portion of the substrate carrier 140 can be a magnetic material (e.g., diamagnetic or ferromagnetic) such that the magnetic field generated by the at least one magnetic device 122 can act on the substrate carrier 140 to provide the magnetic force F. The one or more magnet units 142 can be provided at a side or side portion/section of the substrate carrier 140, for example, at a side or side portion/section facing the at least one magnetic device 122. As an example, the one or more magnet units 142 can be provided at the top side of the substrate carrier 140 when the substrate carrier 140 is in the substantially vertical orientation. The magnetic field and thus the magnetic force F provided by the at least one magnetic device 122 can act on the one or more magnet units 142 to contactlessly hold the substrate carrier 140. As an example, the one or more magnet units 142 can be permanent magnets. In some embodiments, the substrate carrier 140 can not include any devices, such as electronic devices, that require a wired connection to the surroundings of the substrate carrier 140. In other words, the substrate carrier 140 can have no physical or mechanical connection to its surroundings. Having no such physical connections can be beneficial, since a particle generation due to moving elements can be reduced or even avoided.

According to some embodiments, which can be combined with other embodiments described herein, the apparatus 100 further includes a drive system 150 configured for transportation of the substrate carrier 140 along the transportation path. As an example, the transportation path can be a linear transportation path. In some implementations, the drive system 150 can be a magnetic drive system configured to contactlessly move the substrate carrier 140 along the transportation path. In some implementations, the at least one magnetic device 122 can be configured to keep or hold the substrate carrier 140 above the drive system 150.

According to some embodiments, the apparatus 100 is an apparatus for vacuum processing of a substrate 10. The apparatus 100 can include one or more processing tools 160 in the vacuum chamber 110. The one or more processing tools 160 can be arranged along the transportation path. As an example, the one or more processing tools 160 can include at least one tool selected from the group consisting of a deposition source, a sputter source, an etching tool, and any combination thereof. In some embodiments, the apparatus 100 is an apparatus for layer deposition including one or more deposition sources in the vacuum chamber 110 as processing tools 160. The one or more deposition sources can be arranged along the transportation path, such as the linear transportation path. The one or more deposition sources can be sputter deposition sources. As an example, the one or more deposition sources can include sputter cathodes, such as rotatable cathodes. The cathodes can be planar or cylindrical cathodes having a target material to be deposited on the substrate 10.

According to some embodiments, which can be combined with other embodiments described therein, the at least one holding unit 130 is detachably connected to the chamber wall. As an example, the at least one holding unit 130 can be fixed to the chamber wall using fixing means such as screws and/or mechanical clamps. In an alternative embodiment, the at least one holding unit 130 is permanently fixed to the chamber wall. As an example, the at least one holding unit 130 can be welded to the chamber wall.

In some implementations, the at least one magnetic device 122 is detachably connected to the at least one holding unit 130. As an example, the at least one magnetic device 122 can be fixed to the at least one holding unit 130 using fixing means such as screws and/or mechanical clamps. In some embodiments, each holding unit 130 can accommodate or hold one magnetic device 122. In another example, each holding unit 130 can accommodate or hold two or more magnetic devices 122.

The magnetic levitation system 120 can include one holding unit 130, or can include two or more holding units 130. In some implementations, the magnetic levitation system 120 includes an array of holding units 130 and respective magnetic devices 122. The holding units 130 of the array can be arranged along the transportation path. As an example, the holding units 130 and the respective magnetic devices 122 can be arranged above the transportation path. In some embodiments, each holding unit 130 of the array of holding units 130 can be configured to hold one magnetic device 122. In other embodiments, each holding unit 130 of the array of holding units 130 can be configured to hold two more magnetic devices 122.

According to some embodiments, which can be combined with other embodiments described herein, the at least one magnetic device 122 is selected from the group consisting of: an electromagnetic device, a solenoid, a coil, and any combination thereof. As an example, the least one magnetic device 122 can be an electromagnet or a superconducting magnet configured for generating a magnetic field to provide the magnetic force F acting on the substrate carrier 140. The magnetic field can be a static or a dynamic magnetic field.

The embodiments described herein can be utilized for evaporation on large area substrates, e.g., for display manufacturing. Typically, the substrates or substrate carriers, for which the structures and methods according to embodiments described herein are provided, are large area substrates as described herein. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates.

FIG. 2 shows a schematic view of an apparatus 200 for transportation of a substrate 10 according to further embodiments described herein.

According to some embodiments, which can be combined with other embodiments described herein, the chamber wall includes at least one opening. The at least one holding unit 230 can be provided in the opening. As an example, the at least one holding unit 230 can be configured to be at least partially inserted in the opening. In some implementations, the at least one holding unit 230 can be configured to seal the at least one opening. Specifically, the at least one holding unit 230 can seal the at least one opening substantially vacuum-sealed or vacuum-tight. As an example, a sealing device, such as an O-ring or a copper sealing ring, can be used for sealing the at least one opening substantially vacuum-tight. The at least one holding unit 230 can be fixed to the chamber wall using fixing means, such as screws and/or mechanical clamps. In an alternative embodiment, the at least one holding unit 230 is permanently fixed to the chamber wall, for example, by welding. The welding can seal the at least one opening substantially vacuum-tight.

According to some embodiments, at least a portion of the at least one holding unit 230 extends through the chamber wall. In other words, the at least one holding unit 230 can extend beyond a plane defined by the chamber wall towards the vacuum side 101 of the vacuum chamber 110. The at least one magnetic device 122 can be positioned at or in the at least one holding unit 230 so as to be positioned beyond the plane defined by the chamber wall in a direction towards the vacuum side 101. Positioning the at least one magnetic device 122 beyond the plane defined by the chamber wall allows for a positioning of the at least one magnetic device 122 closer to the substrate carrier 140. Specifically, the at least one magnetic device 122 can be positioned closer to the magnet unit 142, such that a sufficient magnetic force F can act on the substrate carrier 140 while a corresponding magnetic field can be minimized.

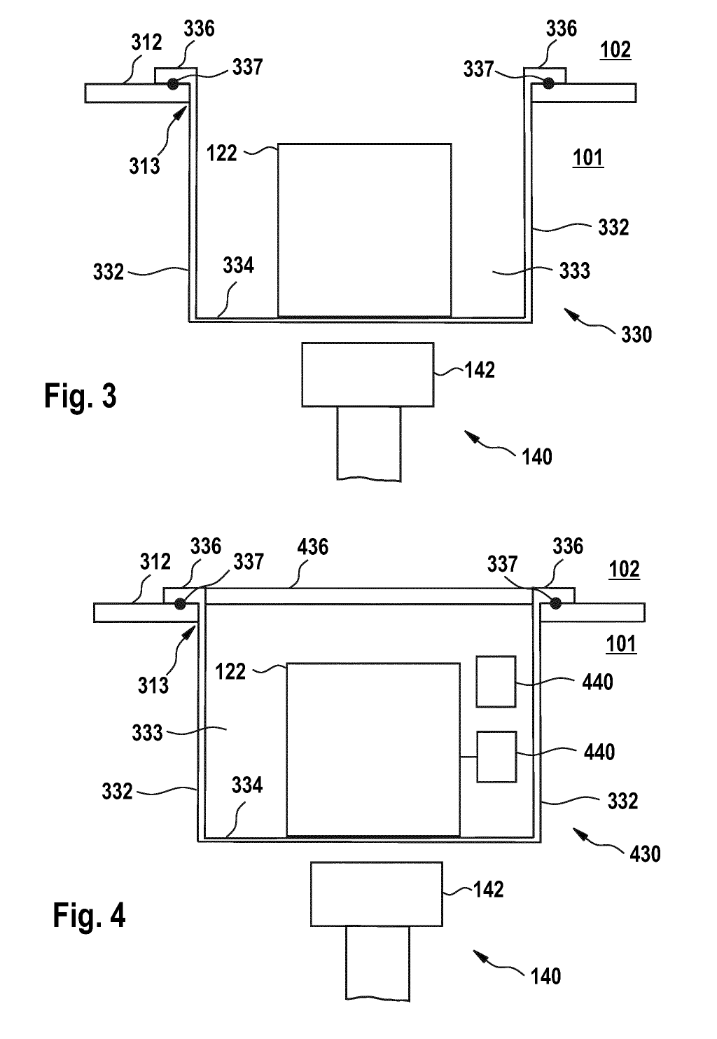

FIG. 3 shows a schematic view of a section of an apparatus for transportation of a substrate according to yet further embodiments described herein.

In some implementations, the at least one holding unit 330 has side walls 332 and a bottom wall 334. The side walls 332 and the bottom wall 334 define a reception space 333. The at least one magnetic device 122 can be positioned in the reception space 333. The side walls 332 and/or the bottom wall 334 can be configured to separate the vacuum side 101 from the atmospheric side 102. The bottom wall 334 can be positioned adjacent to the substrate carrier 140 when the substrate carrier 140 is positioned substantially below the at least one holding unit 330. According to some embodiments, the bottom wall 334 can have a thickness that is less than the thickness of the side walls 332. The reduced thickness of the bottom wall 334 allows for an improved penetration of the magnetic field generated by the at least one magnetic device 122 though the bottom wall 334. As an example, the thickness of the bottom wall can be less than 70%, specifically less than 50%, and more specifically less than 20% of the thickness of the side walls 332.

According to some embodiments, which can be combined with other embodiments described herein, the at least one holding unit 330 can have a cup-like shape or a bowl-like shape. As shown in the example of FIG. 3, the cup or bowl can be inserted in the opening 313 of the chamber wall so as to reach through the chamber wall, for example, the top wall 312. Using the cup or bowl that reaches through the chamber wall allows for a positioning of the at least one magnetic device 122 closer to the substrate carrier 140, and specifically closer to the magnet unit 142.

In some implementations, the at least one holding unit 330 can have a flange portion 336 configured to be attached to the chamber wall. As an example, a sealing device such as an O-ring 337 or a copper sealing ring can be positioned between the flange portion 336 and the chamber wall. The flange portion 336 can have one or more through holes. Fixing means, such as screws, can be inserted into the one or more through holes in order to screw the at least one holding unit 330 to the chamber wall.

FIG. 4 shows a schematic view of a section of an apparatus for transportation of a substrate according to further embodiments described herein.

According to some embodiments, which can be combined with other embodiments described herein, the at least one holding unit 430 includes a lid 436 configured to cover the reception space 333. The lid 436 can be mounted to the at least one holding unit 430, and specifically to the flange portion 336. The lid 436 can be mounted to the at least one holding unit 430 using, for example, one or more hinges (not shown). The lid 436 can cover the at least one magnetic device 122 provided within the reception space 333.

In some embodiments, which can be combined with other embodiments described therein, the holding unit 430 is configured for holding one or more electronic control devices 440 of the magnetic levitation system. As an example, the one or more electronic control devices 440 can include control devices for controlling the at least one magnetic device. The one or more electronic control devices 440 provided in or at the holding unit 430 allows for an access to the one or more electronic control devices 440 from the atmospheric side 102. Maintenance, repair and/or exchange of the one or more electronic control devices 440 can be facilitated.

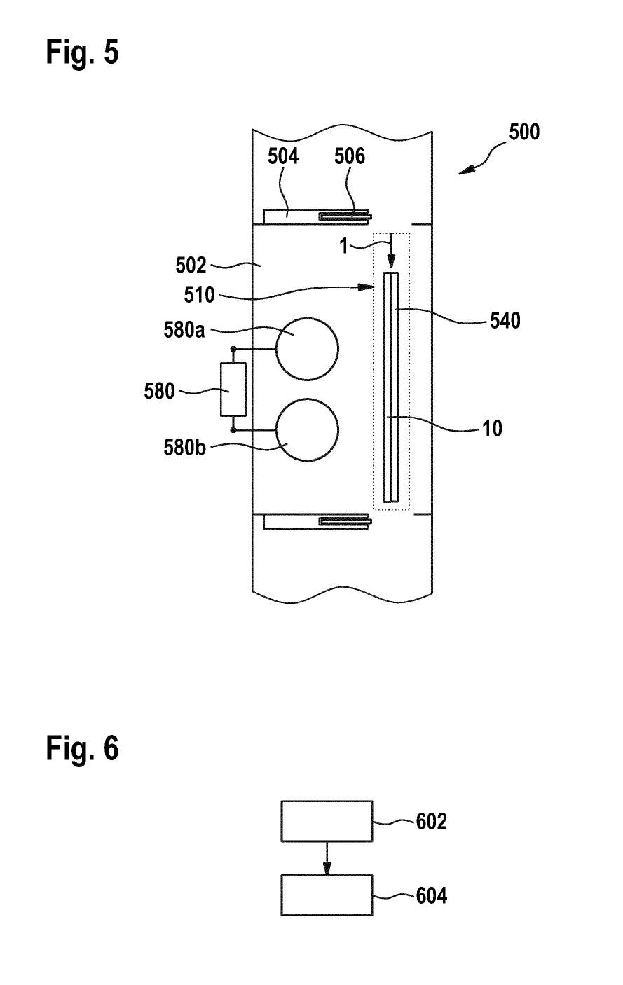

FIG. 5 shows a schematic view of an apparatus 500 for layer deposition, such as sputter deposition, on a substrate 10.

According to some embodiments described herein, the apparatus 500 includes a vacuum chamber 502 (also referred to as “vacuum deposition chamber”, “deposition chamber” or “vacuum processing chamber”), one or more sputter deposition sources, such as a first sputter deposition source 580a and a second sputter deposition source 580b in the vacuum chamber 502, and a substrate carrier 540 for supporting at least one substrate 10 during a sputter deposition process. The substrate carrier 540 can be configured according to any one of the embodiments described herein. The first sputter deposition source 580a and the second sputter deposition source 580b can, for example, be rotatable cathodes having targets of the material to be deposited on the substrate(s).

The apparatus 500 further includes a magnetic levitation system 510 configured according to the embodiments described therein. The magnetic levitation system 510 is configured to transport the substrate carrier 540 without mechanical contact using magnetic fields and respective magnetic forces into, through and/or out of the vacuum chamber 502.

As indicated in FIG. 5, further chambers can be provided adjacent to the vacuum chamber 502. The vacuum chamber 502 can be separated from adjacent chambers by a valve having a valve housing 504 and a valve unit 506. After the substrate carrier 540 with the at least one substrate 10 thereon is inserted into the vacuum chamber 502 as indicated by arrow 1, the valve unit 506 can be closed. The atmosphere in the vacuum chambers 502 can be individually controlled by generating a technical vacuum, for example with vacuum pumps connected to the vacuum chamber, and/or by inserting process gases in a deposition region in the vacuum chamber 502. According to some embodiments, process gases can include inert gases such as argon and/or reactive gases such as oxygen, nitrogen, hydrogen and ammonia (NH3), Ozone (O3), activated gases or the like.

The sputter deposition process can be an RF frequency (RF) sputter deposition process. As an example, the RF sputter deposition process can be used when the material to be deposited on the substrate is a dielectric material. Frequencies used for RF sputter processes can be about 13.56 MHZ or higher.

According to some embodiments described herein, the apparatus 500 can have an AC power supply 580 connected to the one or more sputter deposition sources. As an example, the first sputter deposition source 580a and the second sputter deposition source 580b can be connected to the AC power supply 580 such that the first sputter deposition source 580a and the second sputter deposition source 580b can be biased in an alternating manner. The one or more sputter deposition sources can be connected to the same AC power supply. In other embodiments, each sputter deposition source can have its own AC power supply.

According to embodiments described herein, the sputter deposition process can be conducted as magnetron sputtering. As used herein, “magnetron sputtering” refers to sputtering performed using a magnet assembly, e.g., a unit capable of generating a magnetic field. Such a magnet assembly can consist of a permanent magnet. This permanent magnet can be arranged within a rotatable target or coupled to a planar target in a manner such that the free electrons are trapped within the generated magnetic field generated below the rotatable target surface. Such a magnet assembly can also be arranged coupled to a planar cathode. Magnetron sputtering can be realized by a double magnetron cathode, e.g. the first sputter deposition source 580a and the second sputter deposition source 580b, such as, but not limited to, a TwinMag™ cathode assembly.

The substrate carriers and the apparatuses utilizing the substrate carriers described herein can be used for vertical substrate processing. According to some implementations, the substrate carrier of the present disclosure is configured for holding the at least one substrate in a substantially vertical orientation. The term “vertical substrate processing” is understood to distinguish over “horizontal substrate processing”. For instance, vertical substrate processing relates to a substantially vertical orientation of the substrate carrier and the substrate during substrate processing, wherein a deviation of a few degrees, e.g. up to 10° or even up to 15°, from an exact vertical orientation is still considered as vertical substrate processing. The vertical direction can be substantially parallel to the force of gravity. As an example, the apparatus 500 for sputter deposition on at least one substrate can be configured for sputter deposition on a vertically oriented substrate.

According to some embodiments, the substrate carrier and the substrate are static or dynamic during sputtering of the deposition material. According to some embodiments described herein, a dynamic sputter deposition process can be provided, e.g., for display manufacturing.

FIG. 6 shows a flowchart of a method for maintenance of a magnetic levitation system, for example, of an apparatus according to the embodiments described herein. The magnetic levitation system is configured for a contactless levitation of a substrate carrier in a vacuum chamber. The magnetic levitation system can be configured according to the embodiments described herein. Specifically, the method 600 is a method for maintenance or service of the magnetic levitation system of the apparatus described therein.

The method includes in block 602 an accessing of at least one magnetic device of the magnetic levitation system held by a holding unit from an atmospheric side of the vacuum chamber. In some implementations, the method includes in block 604 a repair or an exchange of the at least one magnetic device from the atmospheric side while a vacuum is maintained inside the vacuum chamber.

According to embodiments described herein, the method for maintenance of a magnetic levitation system can be conducted by means of computer programs, software, computer software products and the interrelated controllers, which can have a CPU, a memory, a user interface, and input and output means being in communication with the corresponding components of the apparatus for processing a large area substrate.

The present disclosure provides an apparatus having a magnetic levitation system (also referred to as “levitation module”) that can include a pass-through device or bowl reaching through the sealing of the vacuum chamber. No atmospheric box is needed. In case of service this levitation module can be exchanged from outside the vacuum chamber and maintained without vacuum breach.

While the foregoing is directed to embodiments of the disclosure, other and further embodiments of the disclosure may be devised without departing from the basic scope thereof, and the scope thereof is determined by the claims that follow.

1. An apparatus for transportation of a substrate, comprising:
a vacuum chamber having a chamber wall configured to separate a vacuum side from an atmospheric side; and
a magnetic levitation system configured for a contactless levitation of a substrate carrier in the vacuum chamber, comprising:
at least one magnetic device configured for providing a magnetic force acting on the substrate carrier during transportation of the substrate carrier in the vacuum chamber along a transportation path; and
at least one holding unit configured to hold the at least one magnetic device being accessible from the atmospheric side.

2. The apparatus of claim 1, wherein the chamber wall includes at least one opening, and wherein the at least one holding unit is provided in the at least one opening.

3. The apparatus of claim 2, wherein the at least one holding unit is configured to seal the at least one opening in the chamber wall.

4. The apparatus of claim 1, wherein the at least one holding unit is detachably connected to the chamber wall.

5. The apparatus of claim 1, wherein the at least one holding unit has side walls and a bottom wall, wherein the side walls and the bottom wall define a reception space, and wherein the at least one magnetic device is positioned in the reception space.

6. The apparatus of claim 5, wherein the at least one holding unit includes a lid configured to cover the reception space.

7. The apparatus of claim 1, wherein at least a portion of the at least one holding unit extends through the chamber wall.

8. The apparatus of claim 1, wherein a distance between the at least one magnetic device and the substrate carrier is less than 10 cm when the magnetic force is acting on the substrate carrier during the transportation of the substrate carrier.

9. The apparatus of claim 1, wherein the at least one holding unit is configured to hold the at least one magnetic device being accessible from the atmospheric side when a vacuum environment is present in the vacuum chamber.

10. The apparatus of claim 1, wherein the magnetic levitation system includes an array of holding units, and wherein the holding units of the array of holding units are arranged along the transportation path.

11. The apparatus of claim 1, wherein the holding unit is configured for holding one or more electronic control devices of the magnetic levitation system.

12. The apparatus of claim 1, wherein the at least one magnetic device is selected from the group consisting of: an electromagnetic device, a solenoid, a coil, and any combination thereof.

13. An for vacuum processing of a substrate, comprising:
a vacuum chamber having a chamber wall configured to separate a vacuum side from an atmospheric side;
a magnetic levitation system configured for a contactless levitation of a substrate carrier in the vacuum chamber, comprising:
at least one magnetic device configured for providing a magnetic force acting on the substrate carrier during transportation of the substrate carrier in the vacuum chamber along a transportation path; and
at least one holding unit configured to hold the at least one magnetic device being accessible from the atmospheric side; and
one or more processing tools in the vacuum chamber, wherein the one or more processing tools are arranged along the transportation path.

14. The apparatus of claim 13, wherein the one or more processing tools include at least one tool selected from the group consisting of: a deposition source and an etching tool.

15. A method for maintenance of a magnetic levitation system, wherein the magnetic levitation system is configured for a contactless levitation of a substrate carrier in a vacuum chamber, the method comprising:
accessing at least one magnetic device of the magnetic levitation system held by a holding unit from an atmospheric side of the vacuum chamber.

16. The apparatus of claim 2, wherein the at least one holding unit is detachably connected to the chamber wall.

17. The apparatus of claim 5, wherein at least a portion of the at least one holding unit extends through the chamber wall.

18. The apparatus of claim 7, wherein the at least one holding unit is configured to hold the at least one magnetic device being accessible from the atmospheric side when a vacuum environment is present in the vacuum chamber.

19. The apparatus of claim 1, wherein the magnetic levitation system is configured to keep the substrate carrier in a suspended or levitating state.

20. The apparatus of claim 13, wherein the magnetic levitation system is configured to keep the substrate carrier in a suspended or levitating state.
